(19) United States
(12) Patent Application Publication
(10) Pub. No.: US 2026/0101800 A1
(43) Pub. Date: Apr. 9, 2026

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventor: Tsunehiro NAKAJIMA, Matsumoto-city (JP)

(73) Assignee: FUJI ELECTRIC CO., LTD., Kawasaki-shi (JP)

(21) Appl. No.: 19/308,602

(22) Filed: Aug. 25, 2025

(30) Foreign Application Priority Data
Oct. 4, 2024 (JP) 2024-175239

(51) Int. Cl. H01L 23/00

(52) U.S. Cl. CPC H10W 72/90; H10W 72/019; H10W 72/01938; H10W 72/923; H10W 72/952

(57) ABSTRACT

A semiconductor device, including: a semiconductor substrate with a main surface; and a surface electrode provided at the main surface of the semiconductor substrate, the surface electrode having a nickel (Ni) film that includes a fibrous-structure Ni film, the fibrous-structure Ni film containing Ni crystal grains grown to form a fibrous shape.

### CROSS REFERENCE TO RELATED APPLICATIONS

This application is based upon and claims the benefit of priority of the prior Japanese Patent Application No. 2024-175239, filed on October 4, 2024, the entire contents of which are incorporated herein by reference.

### BACKGROUND OF THE INVENTION

### 1. Field of the Invention

Embodiments of the disclosure relate to a semiconductor device and a method of manufacturing a semiconductor device.

### 2. Description of the Related Art

Japanese Laid-Open Patent Publication No. H02-007476 describes a technique of using a nickel (Ni) paste containing a nickel powder with a particle size of 50 μm or less to form a back electrode layer containing nearly spherical Ni crystal grains having an average particle size of 10 μm and a maximum particle size of 50 μm. Japanese Laid-Open Patent Publication No. 2007-013106 describes a technique of using an anisotropic conductive resin in which a conductive material such as Au-plated fibrous Ni or Ni metal particles is dispersed in the resin as an adhesive to electrically connect an antenna and wiring.

### SUMMARY OF THE INVENTION

According to an embodiment of the disclosure, a semiconductor device, includes: a semiconductor substrate with a main surface; and a surface electrode provided at the main surface of the semiconductor substrate, the surface electrode having a nickel (Ni) film that includes a fibrous-structure Ni film, the fibrous-structure Ni film containing Ni crystal grains grown to form a fibrous shape.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a semiconductor device according to an embodiment.

FIG. 2 is a cross-sectional view schematically depicting an example of a structure (metal structure) of an Ni film of a back electrode in FIG. 1.

FIG. 3 is a cross-sectional view depicting an example of a structure of a semiconductor module according to the embodiment.

FIG. 4 is flowchart depicting an outline of a method of manufacturing the semiconductor device according to the embodiment.

FIG. 5 is a cross-sectional view depicting a state of the semiconductor module according to the embodiment during assembly.

FIG. 6 is a cross-sectional view depicting a state of the semiconductor module according to the embodiment during assembly.

FIG. 7 is a cross-sectional view schematically depicting an observed state of a structure of an Ni film of a back electrode of an example.

FIG. 8 is a cross-sectional view schematically depicting an observed state of the structure of an Ni Ni film of a back electrode of a reference example.

FIG. 9 is a cross-sectional view schematically depicting an observed state of an example of the structure of the back electrode of the semiconductor device of the reference example.

FIG. 10 is a cross-sectional view schematically depicting an observed state of an example of the structure of the back electrode of the semiconductor device of the reference example.

### DETAILED DESCRIPTION OF THE INVENTION

First, problems associated with the conventional techniques are discussed. In Japanese Laid-Open Patent Publication No. H02-007476, Ni powder is mixed with resin to form a paste, which is printed by screen printing or the like and then solidified to form a back electrode layer, and the thickness of the back electrode layer is as thick as 20 μm. In Japanese Laid-Open Patent Publication No. 2007-013106, the sides of the conductive material in the anisotropic conductive resin is determined according to the pitch of the antenna and wiring.

An outline of an embodiment of the present disclosure is described. (1) A semiconductor device according to an aspect of the present disclosure is a semiconductor device having, at a main surface of a semiconductor substrate, a surface electrode bonded to a component. The surface electrode has an Ni film. The Ni film has a fibrous-structure Ni film that contains Ni crystal grains grown to have a fibrous shape.

According to the disclosure described above, when the surface electrode and the component are soldered, the solder material diffuses toward the semiconductor substrate so as to be detoured in the lateral direction (direction orthogonal to a direction parallel to the thickness of the Ni film) in the fibrous-structure Ni film, along the grain boundaries, and thus, the diffusion distance (length of the diffusion path) of the solder material in the Ni film may be increased. The linear distance that the solder material diffuses in the Ni film in the vertical direction (direction parallel to the thickness of the Ni film) may be reduced by the amount that the diffusion distance of the solder material is increased in the Ni film and thus, the thickness of the Ni film may be reduced. The thickness of the surface electrode (electrode layer) is reduced, whereby the production capacity of the semiconductor device may be increased.

(2) Further, in the semiconductor device according the present disclosure, in (1) above, the Ni film may have a columnar-structure Ni film that contains Ni crystal grains grown to have a columnar shape, the columnar-structure Ni film being in contact with the fibrous-structure Ni film and closer to a surface of the surface electrode than is the fibrous-structure Ni film.

According to the disclosure described above, due to the columnar-structure Ni film between the fibrous-structure Ni film and the solder layer, there are many points of origin (grain boundaries) where the solder material flows in to the Ni film and thus, the strength of the adhesion between the surface electrode and the solder layer may be increased.

(3) Further, in the semiconductor device according to the present disclosure, in (1) or (2), the percentage of the thickness of the fibrous-structure Ni film relative to the thickness of the Ni film may be about 50% or more but not more than 100%.

According to the disclosure described above, the thicker the thickness of the fibrous-structure Ni film is, the shorter the linear distance that the solder material diffuses in the Ni film is, in the vertical direction to the semiconductor substrate.

(4) Further, in the semiconductor device according the present disclosure, in any one of (1) to (3) above, the crystal particle size of the Ni crystal grains of the fibrous-structure Ni film may be larger than the crystal particle size of the Ni crystal grains of the columnar-structure Ni film.

According to the disclosure described above, the larger the crystal particle size of the Ni crystal grains of the fibrous-structure Ni film is, the shorter the linear distance that the solder material diffuses in the Ni film, in the vertical direction to the semiconductor substrate may be.

(5) Further, in the semiconductor device according to the present disclosure, in any one of (1) to (4) above, the crystal particle size of the Ni crystal grains of the fibrous-structure Ni film may be 0.02 μm or more but not more than 0.2 μm.

According to the disclosure described above, the larger the crystal particle size of the Ni crystal grains of fibrous-structure Ni film is, the shorter the linear distance that the solder material diffuses in the Ni film, in the vertical direction to the semiconductor substrate may be.

(6) Further, in the semiconductor device according to the present disclosure, in any one of (2) to (4) above, the crystal particle size of the Ni crystal grains of the columnar-structure Ni film may be 0.01 μm or more but not more than 0.05 μm.

According to the disclosure described above, the smaller the crystal particle size of the Ni crystal grains of the columnar-structure Ni film is, the greater the number of points of origin (grain boundaries) where the solder material flows in to the Ni film is and therefore, the strength of the adhesion between the surface electrode and the solder layer may be increased.

(7) A method of manufacturing a semiconductor device according to one aspect of the present disclosure is a method of manufacturing a semiconductor device having, at a main surface of a semiconductor substrate, a surface electrode soldered to a component. The method includes a deposition process of forming an Ni film at the main surface of the semiconductor substrate, as the surface electrode. The deposition process includes performing a first sputtering of a temperature of 25 degrees C or more but not more than 50 degrees C to thereby form the Ni film.

According to the disclosure described above, a fibrous-structure Ni film may be deposited as the Ni film.

(8) Further, in the method of manufacturing the semiconductor device according to the present disclosure, in (7) above, in the deposition process, the first sputtering may be performed under an Ar atmosphere of a gas pressure of 0.2 Pa or more but not more than 1.2 Pa.

According to the disclosure described above, the fibrous-structure Ni film may be deposited as the Ni film.

(9) Further, in the method of manufacturing the semiconductor device according to the present disclosure, in (7) or (8) above, the deposition process may include: as a first process, performing the first sputtering so as to form a first portion of the Ni film, and as a second process, performing a second sputtering under a temperature of 100 degrees C or higher but not more than 180 degrees C so as to form a second portion of the Ni film, the second portion excluding the first portion, and the second process being performed after the first process.

According to the disclosure described above, the fibrous-structure Ni film may be deposited as the first portion of the Ni film and the columnar-structure Ni film may be formed as the second portion of the Ni film.

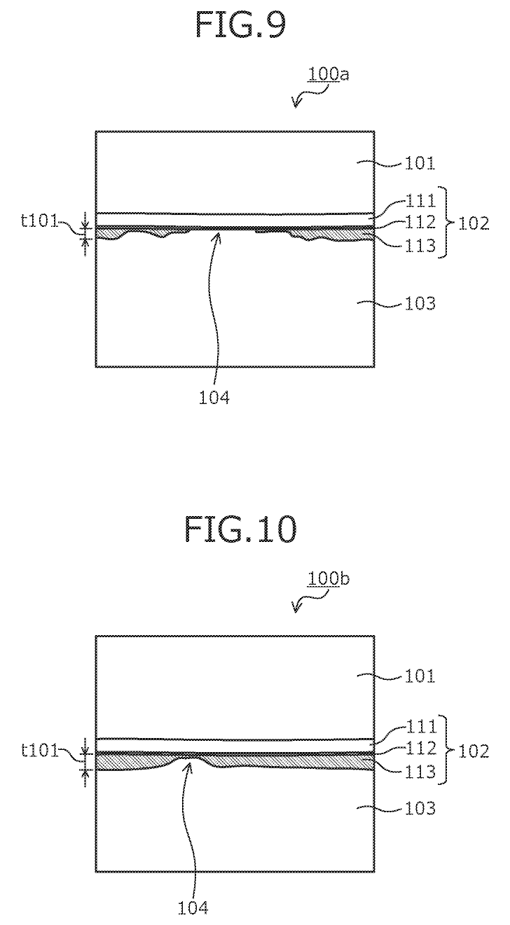

Findings underlying the present disclosure are discussed. First, a structure of a semiconductor device of a reference example is described. FIG. 8 is a cross-sectional view schematically depicting an observed state of the structure of an Ni film of a back electrode of the reference example. FIG. 8 depicts a state of the structure of an Ni film 113 in FIGS. 9 and 10. In FIG. 8, arrows schematically depict a portion of diffusion paths 52 of solder material that diffuses along grain boundaries of the Ni film 113. FIGS. 9 and 10 are cross-sectional views schematically depicting observed states of examples of the structure of the back electrode of the semiconductor device of the reference example. Semiconductor devices 100a, 100b of the reference example depicted in FIGS. 9 and 10 have a surface electrode (hereinafter, back electrode) 102 at a back surface of a semiconductor substrate 101, the back electrode 102 is soldered on a conductive plate (not depicted) of an insulated substrate of a package via a solder layer 103 and is thereby mounted to the package.

The back electrode 102 has a four-layer structure in which an aluminum (Al) film 111, a titanium (Ti) film 112, a nickel (Ni) film 113 (hatched portion), and a gold (Au) film (not depicted) are sequentially stacked (in the order stated) on the back surface of the semiconductor substrate 101 by sputtering. Due to this layered structure, predetermined electrical performance (for example, electrical conductivity, etc.), thermal performance (for example, heat dissipation, etc.), and mechanical strength of the back electrode 102 are ensured. The semiconductor devices 100a, 100b in FIGS. 9 and 10 each have the same structure excluding a thickness t101 of the Ni film 113. The Ni film 113 greatly contributes to the electrical performance, the thermal performance and the mechanical strength of the back electrode 102, and of the metal films forming the back electrode 102, is the thickest film. The Au film has good solder wettability, and when the back electrode 102 is soldered, the Au film is eluted, diffuses in the solder layer 103 and disappears by forming an alloy with the solder material (i.e., solder erosion of the Au film).

As depicted in FIG. 9, when the thickness t101 of the Ni film 113 is thin (for example, about 0.25 μm), the Ni film 113 disappears locally due to solder erosion 104 during the soldering of the back electrode 102, whereby the solder layer 103 and a Ti film 112, which is a lower layer of the Ni film 113, contact each other. As depicted in FIG. 10, when the thickness t101 of the Ni film 113 is sufficient (for example, about 0.5 μm), the Ni film 113 may be left in an entire area between the solder layer 103 and the Ti film 112, however, the thickness t101 of the Ni film 113 becomes thinner locally due to the solder erosion 104 during the soldering of the back electrode 102. The solder erosion 104 of the Ni film 113 is a phenomenon in which the solder material (main component being, for example, tin (Sn)) of the solder layer 103 is eluted and diffuses in the Ni film 113, generating a compound (alloy) with the Ni in the Ni film 113, and disappears by becoming recessed toward the Ti film 112, at locations where the compound (alloy) is generated.

While the alloying due to the solder erosion 104 of the Ni film 113 increases the strength of the adhesion between the back electrode 102 and the solder layer 103, alloying of the solder material and the Ti film 112 is difficult. Therefore, a design is adopted in which soldering of the back electrode 102 is performed by leaving the Ni film 113 in the entire area between the solder layer 103 and the Ti film 112 as depicted in FIG. 10 so that the solder material of the solder layer 103 does not pass the Ni film 113 and reach the Ti film 112. Further, in general, during deposition of the back electrode 102, temperature control is not actively performed and thus, variation in the crystal grain size of the Ni film 113 occurs, leading to variation in the thickness t101 of the Ni film 113. Therefore, in anticipation of the decrease in the thickness due to the solder erosion 104 and with consideration of variation in the thickness t101 during deposition of the Ni film 113, the Ni film 113 has to be deposited to have an excessive thickness. As a result, production capacity of the product (semiconductor device) decreases while manufacturing cost and product unit price increase and thus, preferably, the thickness t101 of the Ni film 113 is as thin as possible.

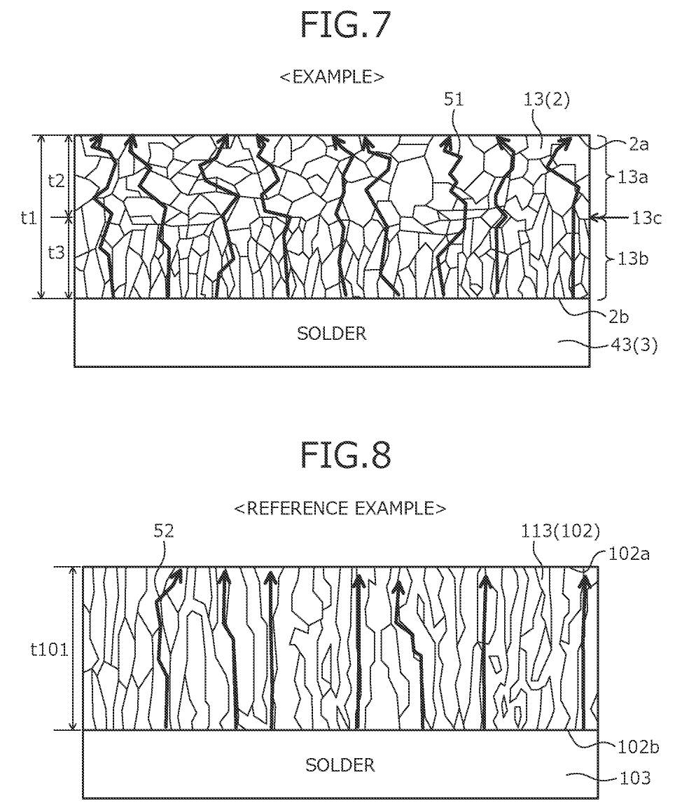

As depicted in FIG. 8, the Ni film 113 is deposited under a temperature and gas pressure for general columnar growth and is constituted by columnar Ni crystal grains grown in a direction toward the solder layer 103 (a surface 102b of the Ni film 113), i.e., a direction substantially orthogonal to a surface 102a of the Ti film 112. Initially, during the soldering of the back electrode 102, the solder material diffuses in to the Ni film 113 along the grain boundaries and thus, lengths of the diffusion paths (paths along which the solder material diffuses in the Ni film 113 along the grain boundaries and reaches the Ti film 112) 52 of the solder material in the Ni film 113 are nearly a same as the thickness t101 of the Ni film 113. The present inventor, as a result of earnest research, found that the lengths of diffusion paths 51 of the solder material in an Ni film 13 may be made longer than a thickness t1 of an Ni film 13 by growing the crystal grains of the Ni film 13 to have a fibrous shape (spherical shape) (refer to later-described FIG. 7). The thickness t1 of the Ni film 13 may be reduced by the amount that the length of each of the diffusion paths 51 of the solder material in the Ni film 13 is increased. The present disclosure is based on this knowledge.

In the present embodiment, the thickness of an Ni film of a back electrode (electrode layer) is reduced.

Embodiments of a semiconductor device and a method of manufacturing a semiconductor device according to the present disclosure are described in detail with reference to the accompanying drawings. In the present description and accompanying drawings, layers and regions prefixed with n or p mean that majority carriers are electrons or holes. Additionally, + or - appended to n or p means that the impurity concentration is higher or lower, respectively, than layers and regions without + or -. In the description of the embodiments below and the accompanying drawings, main portions that are identical are given the same reference numerals and are not repeatedly described.

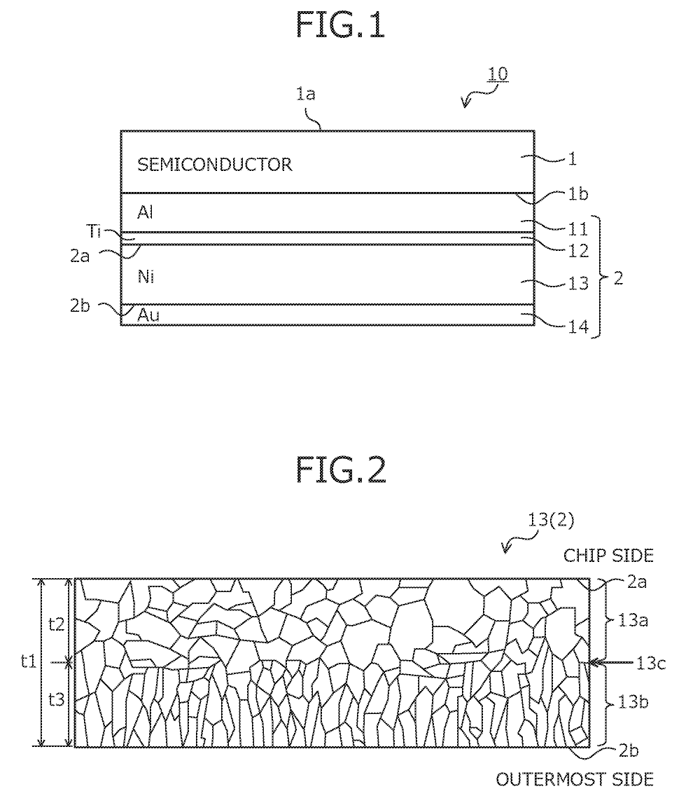

A semiconductor device according to an embodiment solving the problems discussed above is described. FIG. 1 is a cross-sectional view depicting a structure of the semiconductor device according to the embodiment. FIG. 2 is a cross-sectional view schematically depicting an example of a structure (metal structure) of an Ni film of a back electrode in FIG. 1. A semiconductor device 10 according to the embodiment depicted in FIG. 1 has a semiconductor substrate (semiconductor chip) 1 and surface electrodes (hereinafter, a front electrode (not depicted) and a back electrode 2) provided respectively at main surfaces (a front surface 1a and a back surface 1b) of the semiconductor substrate 1 and the back electrode 2 has a multilayer structure in which multiple predetermined metal films are stacked, whereby the semiconductor device 10 has a structure suitable for soldering during mounting to a package. A material of the semiconductor substrate 1 may be silicon (Si), silicon carbide (SiC), or the like.

In an active region, in the semiconductor substrate 1, at the front surface 1a, a predetermined front device structure (not depicted) is provided. The front device structure, for example, is an insulated gate structure in an instance in which the semiconductor device 10 is an insulated gate bipolar transistor (IGBT) or a metal oxide semiconductor field effect transistor (MOSFET) having insulated gates with a metal-oxide-semiconductor three-layered structure or is an anode region in an instance in which the semiconductor device 10 is a diode. The active region is a region through which a main current flows when the semiconductor device 10 is on.

The active region, for example, is provided in substantially a center (chip center) of the semiconductor substrate. Between the active region and an end (chip end) of the semiconductor substrate 1 is an edge termination region. The edge termination region surrounds a periphery of the active region in a plan view and has a function of relaxing electric field in the semiconductor substrate 1, near the front surface 1a, and sustaining a breakdown voltage. In the edge termination region, for example, a general voltage withstanding structure (not depicted) such as a field limiting ring (FLR), a junction termination extension (JTE) structure, or a guard ring is disposed. The breakdown voltage is a voltage limit at which no malfunction or destruction of the semiconductor device 10 occurs.

In an instance in which the semiconductor device 10 is a vertical type, in the semiconductor substrate 1, at the back surface thereof, a predetermined back device structure (not depicted) is provided. The back device structure, for example, is a drain region of a MOSFET, a collector region of an IGBT, or a cathode region of a diode. The back device structure is formed in the semiconductor substrate 1, in an entire area thereof at the back surface by ion implantation of a dopant from the back surface of the semiconductor substrate 1. In an instance in which the semiconductor substrate 1 is a bulk substrate, the front device structure and the back device structure are formed in the semiconductor substrate 1. In an instance in which the semiconductor substrate 1 is an epitaxial substrate in which multiple epitaxial layers are stacked on a starting substrate (bulk substrate), the starting substrate constitutes the back device structure and the front device structure is formed in the epitaxial layers.

The front electrode is provided at the front surface 1a of the semiconductor substrate 1 and is electrically connected to the front device structure. The front electrode, for example, is a source electrode of a MOSFET, an emitter electrode of an IGBT, or an anode electrode of a diode. The back electrode 2 is provided in an entire area of the back surface 1b of the semiconductor substrate 1. In an instance in which the semiconductor device 10 is a vertical type, the back electrode 2, for example, is a drain electrode of a MOSFET, a collector electrode of an IGBT, or a cathode electrode of a diode, and is electrically connected to the back device structure. In an instance in which the semiconductor device 10 is a horizontal type, the back electrode 2 is fixed to a predetermined potential (for example, ground potential, base potential, etc. of an IGBT or a MOSFET) of the semiconductor substrate 1.

In particular, the back electrode 2 has a four-layer structure in which an aluminum (Al) film 11, a titanium (Ti) film 12, a nickel (Ni) film 13, and a gold (Au) film 14 are sequentially stacked in the order stated, on the back surface 1b of the semiconductor substrate 1 by sputtering. This stacked structure ensures predetermined electrical performance (for example, electrical conductivity, etc.), thermal performance (for example, heat dissipation, etc.), and mechanical strength of the back electrode 2. The Al film 11 forms an ohmic contact with the semiconductor substrate 1. Instead of the Al film 11, an Al alloy film containing Al as a main substituent, for example, an aluminum-silicon (Al-Si) film or the like may be provided. The Al film 11 may be omitted and the Ti film 12 may form an ohmic contact with the semiconductor substrate 1.

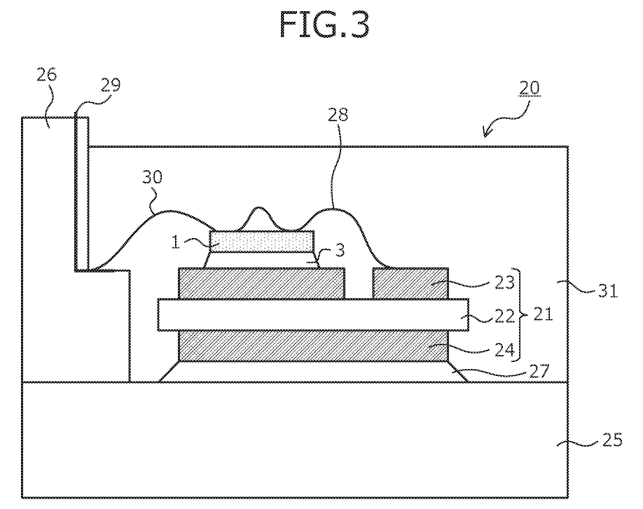

The Ti film 12 does not easily alloy with tin (Sn), which is a main substituent of the solder material of the solder layer 3 (refer to FIG. 3), and the Ti film 12 functions as a barrier metal for preventing the solder material of the solder layer 3 from reaching the Al film 11 when the back electrode 2 is mounted to the package via the solder layer 3. The Ni film 13 has a function of increasing the strength adhesion with respect to the solder layer 3. The Ni film 13 has a fibrous-structure Ni film 13a (refer to FIG. 2). Preferably, the Ni film 13 has a columnar-structure Ni film 13b between the fibrous-structure Ni film 13a and the Au film 14 (refer to FIG. 2). The fibrous-structure Ni film 13a and the columnar-structure Ni film 13b are described hereinafter. The Au film 14 prevents oxidation of a surface 2b of the Ni film 13 and imparts solder wettability to the surface 2b of the Ni film 13.

As depicted in FIG. 2, the Ni film 13 has a single-layer structure constituted by the fibrous-structure Ni film 13a or a two-layer structure constituted by the fibrous-structure Ni film 13a and the columnar-structure Ni film 13b. In other words, a ratio of the thickness t2 of the fibrous-structure Ni film 13a to the thickness t1 of the Ni film 13 (hereinafter, percentage of the fibrous-structure Ni film 13a relative to the Ni film 13) is 100% or less and preferably, for example, may be about 50% or more. The thickness t1 of the Ni film 13, for example, is about 0.5 μm or more but not more than 1.5 μm. In an instance in which the percentage of the fibrous-structure Ni film 13a relative to the Ni film 13 is 100% (not depicted), the fibrous-structure Ni film 13a is the Ni film 13 itself, has a surface facing the semiconductor substrate 1 (chip side) and in contact with a surface 2a of the Ti film 12, and has a surface constituting an outermost side of the back electrode 2 (the surface 2b of the Ni film 13) in contact with the Au film 14.

In an instance in which the percentage of the fibrous-structure Ni film 13a relative to the Ni film 13 is less than 100%, a total thickness of the fibrous-structure Ni film 13a and the columnar-structure Ni film 13b is the thickness t1 of the Ni film 13. In FIG. 2, an instance in which the percentage of the fibrous-structure Ni film 13a relative to the Ni film 13 is substantially 50%, in other words, an instance in which the thickness t2 of the fibrous-structure Ni film 13a and thickness t3 of the columnar-structure Ni film 13b are substantially the same is depicted. In this instance, the fibrous-structure Ni film 13a, at the surface thereof on the chip side, is in contact with the surface 2a of the Ti film 12 and at the surface on the outermost side, is in contact with the columnar-structure Ni film 13b. The columnar-structure Ni film 13b, at the outermost side (the surface 2b of the Ni film 13), is in contact with the Au film 14. The greater is the thickness t2 of the fibrous-structure Ni film 13a, the thinner the thickness t1 of the Ni film 13 may be.

The fibrous-structure Ni film 13a is formed by Ni crystal grains grown in fibrous shapes (spherical shapes) on the surface 2a of the Ti film 12 and has a fibrous structure in which the fibrous-shaped crystal grains are densely stacked without gaps. The fibrous-structure Ni film 13a is deposited by sputtering under an argon (Ar) atmosphere of a low pressure of, for example, about 0.2 Pa or higher but not more than 1.2 Pa and a low temperature of about room temperature (for example, about 25 C degrees) or higher but not more than 50 degrees C, using the Thornton model. The Thornton model is a zone model of crystal structure changes of a vapor-deposited metal film established by Thornton, and has two axes including substrate temperature T (=T/Tm) during deposition of the vapor-deposited film relative to the melting point Tm of a metal material of the vapor-deposited film, and Ar gas pressure during deposition of the vapor-deposited film.

Grain boundaries of the fibrous-structure Ni film 13a do not substantially extend linearly in a vertical direction from the outermost side to the chip side. Therefore, the solder material eluted in the fibrous-structure Ni film 13a during soldering of the back electrode 2 does not easily diffuse in the vertical direction from the outermost side to the chip side. The diffusion paths (paths along which the solder material diffuses along the grain boundaries in the Ni film 13 and reaches the Ti film 12) 51 of the solder material in the Ni film 13 detour in a lateral direction (direction orthogonal to the vertical direction) along grain boundaries in the fibrous-structure Ni film 13a and are longer than the diffusion paths 52 (refer to FIG. 8) in the columnar-structure Ni film 113 of the reference example. The crystal particle size (diameter) of the Ni crystal grains of the fibrous-structure Ni film 13a is larger than the crystal particle size (width) of the Ni crystal grains of the columnar-structure Ni film 13b and, for example, is about 0.02 μm or more, but not more than 0.2 μm.

The columnar-structure Ni film 13b is constituted by Ni crystal grains grown in column-like (linear) shapes in a direction to the outermost side and substantially orthogonal to the surface of the fibrous-structure Ni film 13a. In other words, the columnar-structure Ni film 13b is deposited by sputtering under the same conditions (temperature and gas pressure) as those of the Ni film 113 of the reference example. As indicated by the Thornton model, the deposition temperature for the columnar-structure Ni film 13b is higher than the deposition temperature for the fibrous-structure Ni film 13a and is, for example, about 100 degrees C or higher, but not more than 180 degrees C. The crystal structure of the Ni film 13 may be observed by, for example, a scanning electron microscope (SEM) or a transmission electron microscope (TEM).

The grain boundaries of the columnar-structure Ni film 13b extend substantially linearly in a direction from the outermost side to the chip side. In the columnar-structure Ni film 13b, the solder material of the solder layer 3 (refer to FIG. 3) diffuses substantially linearly in the vertical direction from the outermost side to the chip side and thus, the solder material easily diffuses in the columnar-structure Ni film 13b. At portions where the solder material diffuses, the Ni film 13 is eroded and alloyed with the solder layer 3, thereby increasing the strength of the adhesion between the back electrode 2 and the solder layer 3. Solder erosion of the Ni film 13 is a phenomenon in which the solder material (Sn being a main component) of the solder layer 3 is eluted and diffuses in the Ni film 13, generating an alloy with the Ni in the Ni film 13, and disappears by becoming recessed toward the Ti film 12, at locations where the alloy is generated. The crystal particle size of the Ni crystal grains of the columnar-structure Ni film 13b is, for example, about 0.01 μm or more, but not more than 0.05 μm. The maximum length of the Ni crystal grains of the columnar-structure Ni film 13b is a same as the thickness t3 of the columnar-structure Ni film 13b.

A semiconductor module (package) according to the embodiment in which the semiconductor device 10 according to the embodiment depicted in FIGS. 1 and 2 is mounted is described. FIG. 3 is a cross-sectional view depicting an example of a structure of the semiconductor module according to the embodiment. In FIG. 3, surface electrodes (the front electrode, and the back electrode 2 in FIG. 1) respectively at the main surfaces of the semiconductor substrate 1, an alloy layer 4 (refer to later-described FIG. 6) of the back electrode 2 and the solder layer 3, and the alloy layer 5 (refer to later-described FIG. 6) of the solder layer 3 and a conductive plate 23 are not depicted. In a semiconductor module 20 according to the embodiment depicted in FIG. 3, the semiconductor device 10 according to the embodiment depicted in FIGS. 1 and 2 described above is housed (mounted) in a case or the like by a general assembly process and the semiconductor module 20 includes a semiconductor chip (the semiconductor substrate 1 in which the semiconductor device 10 is fabricated), a stacked substrate 21, a metal substrate 25, and a case 26.

The stacked substrate 21 has a wiring pattern of a predetermined circuit formed by the conductive plate (component) 23 such as a copper (Cu) foil at a front surface of an insulated substrate 22 such as a ceramic substrate that ensures insulation and has a conductive plate 24 such as a Cu foil at a back surface of the insulated substrate 22. The conductive plate 24 is bonded to the metal substrate 25 by a bonding material 27 such as solder. The metal substrate 25 has a cooling structure such as heat dissipation fins (not depicted). The back electrode 2 of the semiconductor substrate 1 (refer to FIG. 1) is bonded to the conductive plate 23 by the solder layer 3. The solder layer 3 is formed by a lead (Pb) free solder of a general composition such as a SAC 305 (containing Sn as a main component, 3.0% (Ag) and 0.5% Cu). A first end of a conductive wire 28 is bonded to the front electrode (not depicted) of the semiconductor substrate 1. A second end of the wire 28 is bonded to the conductive plate 23.

A periphery of the semiconductor substrate 1 is surrounded by the case 26. The case 26, for example, is a resin molded product integrally molded with an external connection terminal 29. A first end of the external connection terminal 29 is electrically connected to the front electrode of the semiconductor substrate 1 by a conductive wire 30. A second end of the external connection terminal 29 is exposed outside of the case 26. The case 26 is bonded to a layered assembly including the semiconductor substrate 1, the stacked substrate 21, and the metal substrate 25 (for example, is bonded along the periphery of the metal substrate 25) via an adhesive. The case 26 is filled with an encapsulant 31 such as a hard resin like an epoxy. The encapsulant 31 insulates and protects the semiconductor substrate 1, the wires 28, 30, and the conductive plate 23. While not depicted, the semiconductor substrate 1 may be mounted to a case-free semiconductor module free of the case 26.

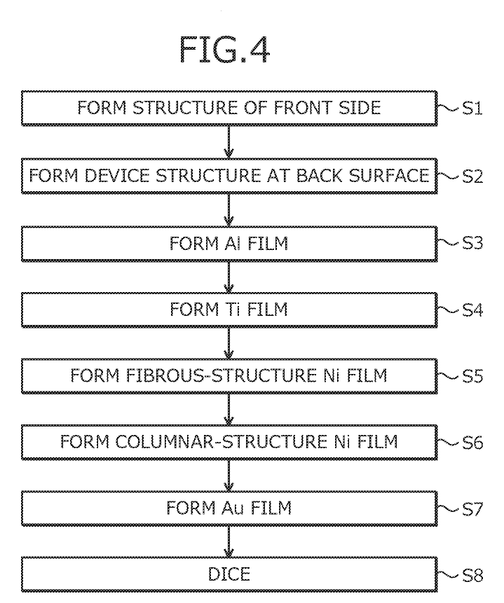

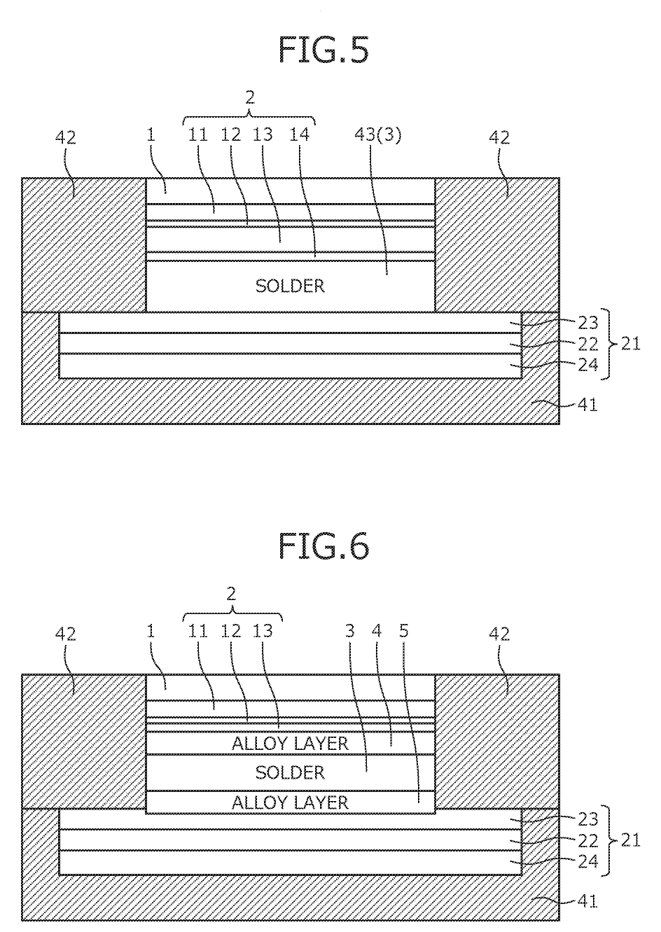

A method of manufacturing the semiconductor device 10 according to the embodiment depicted in FIGS. 1 and 2 and an assembly method of the semiconductor module 20 according to the embodiment depicted in FIG. 3 are described. FIG. 4 is flowchart depicting an outline of the method of manufacturing the semiconductor device according to the embodiment. FIGS. 5 and 6 are cross-sectional views depicting states of the semiconductor module according to the embodiment during assembly. FIG. 7 is a cross-sectional view schematically depicting an observed state of the structure of an Ni film of a back electrode of an example. FIG. 7 schematically depicts the Ni film 13 of the semiconductor device 10 (hereinafter, the example) fabricated according to the method of manufacturing the semiconductor device according to the embodiment. Further, FIG. 7 schematically depicts, by arrows, a portion of the diffusion paths 51 along which the solder material diffuses along the grain boundaries of the Ni film 13.

First, a structure at a front surface (the front surface 1a of the semiconductor substrate 1) of a semiconductor wafer constituting the semiconductor substrate 1 is formed (step S1). The structure at the front surface of the semiconductor wafer includes a predetermined front device structure of the semiconductor substrate 1 and a front electrode. Next, at a back surface (the back surface 1b of the semiconductor substrate 1) of the semiconductor wafer, a predetermined back device structure of the semiconductor substrate 1 is formed (step S2). Next, by sputtering, the Al film 11 is deposited at the back surface of the semiconductor wafer (step S3). Next, by sputtering, the Ti film 12 is deposited at the surface of the Al film 11 (step S4). The thickness of the Ti film 12 is relatively thin, for example, about 0.1 μm and thus, when the Ti film 12 is deposited by sputtering, the temperature of the semiconductor wafer does not increase.

Next, the fibrous-structure Ni film (first portion) 13a is deposited at the surface 2a of the Ti film 12 by sputtering (first sputtering) (step S5: deposition process, first process). In the process at step S5, for example, the semiconductor wafer is directly cooled or indirectly cooled via a wafer stage, and the Ni film 13 is deposited under an Ar atmosphere of a low temperature within the deposition temperature range described above and a low gas pressure within the range described above while increases in the temperature of the semiconductor wafer are suppressed by the acceleration energy of the sputtering, whereby Ni crystal grains with a fibrous structure and having a crystal particle size within the range described above are grown thereby forming the fibrous-structure Ni film 13a. When sputtering equipment has a cooling structure (for example, a cooling structure using flowing water) with a cooling capability sufficient to counter the temperature increases of the semiconductor wafer due to the acceleration energy of the sputtering and cool the semiconductor wafer to room temperature, relatively low-cost expansion is possible.

Next, the columnar-structure Ni film (second portion) 13b is deposited at the surface of the fibrous-structure Ni film 13a by sputtering (second sputtering) (step S6: deposition process, second process). In the process at step S6, for example, the rise in temperature of the semiconductor wafer due to the acceleration energy of the sputtering is used without performing heating or the semiconductor wafer is directly or indirectly heated via the wafer stage by a heat treatment to gradually increase the temperature of the semiconductor wafer to be within the deposition temperature range described above, which is higher than the deposition temperature at step S5, and thereby deposit the Ni film 13. As a result, Ni crystal grains with a columnar structure and having a crystal particle size within the range described above are grown, thereby forming the columnar-structure Ni film 13b. In other words, the Thornton model is used to suitably adjust the deposition temperature of the Ni film 13, whereby the shape of the crystal grains of the Ni film 13 may be changed.

In the process at step S6, existing sputtering equipment used to deposit the Ni film 113 in the reference example depicted in FIG. 8 may be used. In the process at step S6, when the deposition temperature for the columnar-structure Ni film 13b increases and exceeds the upper limit described above, the load on the target and sputtering equipment increases and after the deposition of the columnar-structure Ni film 13b, the capability of the cooling mechanism for returning the temperature of the semiconductor wafer to room temperature has to be increased. Further, power loss during the process at step S6 also increases. The processes at steps S5 and S6 are performed in respectively different chambers (treatment furnaces) and thus, cleaning of each of the chambers is facilitated. In an instance in which the percentage of the fibrous-structure Ni film 13a relative to the Ni film 13 is 100%, the process at step S6 may be omitted.

Next, the Au film 14 is deposited at the surface 2b of the Ni film 13 by sputtering (step S7). The described processes at steps S3 to S7 are performed in batches in each of the chambers. Next, the semiconductor wafer is diced (cut) into individual semiconductor chips (the semiconductor substrates 1) (step S8), thereby completing the semiconductor device 10 depicted in FIGS. 1 and 2. In an assembly process of the semiconductor module 20 in which the semiconductor substrate 1 is mounted, the semiconductor substrate 1 having the semiconductor device 10 fabricated therein, for example, as depicted in FIG. 5, the semiconductor substrate 1 is soldered to the stacked substrate 21, using jigs 41, 42 that contain carbon.

In particular, for example, the stacked substrate 21 is disposed at a predetermined position on the lower jig 41 for solder bonding. At the main surfaces of the stacked substrate 21, the conductive plates 23, 24 are respectively bonded, and the stacked substrate 21 is disposed on the jig 41 with the conductive plate 23 side facing upward. Next, a solder plate 43 of substantially a same size as a size (chip size) of the semiconductor substrate 1 is disposed on the conductive plate 23, using the upper jig 42 for positioning. The same jig 42 for positioning is further used to dispose the semiconductor substrate 1 on the solder plate 43. The semiconductor substrate 1 is disposed with the back electrode 2 facing downward, bringing the outermost surface (surface of the Au film 14) of the back electrode 2 and the upper surface of the solder plate 43 in contact with each other. In this state, the semiconductor substrate 1, the solder plate 43, and the stacked substrate 21 are inserted in a heat treatment furnace (not depicted), for each of the jigs 41, 42.

Further, as depicted in FIG. 6, the semiconductor substrate 1, the solder plate 43, and the stacked substrate 21 are heated by a heat treatment (reflow) under a hydrogen (H₂) atmosphere. The Au film 14 of the back electrode 2 is eluted and diffuses in the solder plate 43, forms an alloy with the solder material (for example, the main substituent Sn) and thereby disappears. As a result, solder wettability is imparted to the surface 2b of the Ni film 13 (refer to FIGS. 1 and 2) of the back electrode 2. The solder material of the solder plate 43 is eluted and diffuses in the Ni film 13, a portion of the solder plate 43 and a portion of the Ni film 13 form an alloy (the solder erosion of the Ni film 13: not depicted), and the alloy layer 4 is formed between the solder plate 43 and the back electrode 2. The alloy formed by the solder erosion of the Ni film 13 ensures the strength of the adhesion between the back electrode 2 and the solder layer 3.

Depending on the solder type and soldering conditions of the solder plate 43, preferably, the columnar-structure Ni film 13b may be disposed between the solder plate 43 and the fibrous-structure Ni film 13a. In an instance in which the Ni film 13 has the columnar-structure Ni film 13b, the solder material is eluted in the columnar-structure Ni film 13b from the surface 2b of the Ni film 13 and diffuses substantially linearly in the columnar-structure Ni film 13b, along the grain boundaries, in a direction to the semiconductor substrate 1. In the columnar-structure Ni film 13b, the crystal particle size of the Ni crystal grains is smaller than that in the fibrous-structure Ni film 13a and has more points of origin (grain boundaries) where the solder material flows in. Thus, the strength of the adhesion between the back electrode 2 and the solder layer 3 increases. When the solder material of the solder plate 43 passes a boundary 13c between the columnar-structure Ni film 13b and the fibrous-structure Ni film 13a and is eluted in the fibrous-structure Ni film 13a, the solder material diffuses toward the semiconductor substrate 1 so as to be detoured in the lateral direction in the fibrous-structure Ni film 13a, along the grain boundaries.

Thus, due to the fibrous-structure Ni film 13a, the diffusion paths 51 of the solder material in the Ni film 13 may be made longer than the diffusion paths 52 (refer to FIG. 8) of the solder material in the columnar-structure Ni film 113 of the reference example. The larger the crystal particle size of the Ni crystal grains of the fibrous-structure Ni film 13a is, the more the solder material diffuses in the lateral direction along the grain boundaries in the fibrous-structure Ni film 13a and thus, the linear distance that the solder material diffuses in the Ni film 13, from the surface 2b of the Ni film 13 to the semiconductor substrate 1 may be shortened. For example, in an instance in which the thickness t1 of the Ni film 13 (refer to FIG. 7) of the example is substantially a same as the thickness t101 of the Ni film 113 of the reference example (refer to FIG. 8), the diffusion paths 51 of the solder material in the Ni film 13 of the example may be made, at maximum, about 54% longer than the diffusion paths 52 of the solder material in the Ni film 113 of the reference example.

The diffusion paths 51 of the solder material in the Ni film 13 are relatively long and thus, the solder material does not easily pass through the Ni film 13 and reach the Ti film 12. Therefore, the thickness t1 of the Ni film 13 may be reduced by the amount that the diffusion paths 51 of the solder material in the Ni film 13 are increased in length. For example, in an instance in which the Ni film 13 is configured by the fibrous-structure Ni film 13a and the columnar-structure Ni film 13b of substantially the same thicknesses t2, t3, the thickness of the Ni film 13 lost by solder erosion may be reduced by about 30% compared to the thickness of the Ni film 113 (the reference example) lost by solder erosion. In other words, the thickness t1 of the Ni film 13 may be made about 30% thinner (for example, may be made about 0.5 μm) than the thickness t101 of the Ni film 113 (for example, about 0.7 μm) of the semiconductor device 100b of the reference example.

The alloy layer 4 having a thickness that is a same as the linear distance that the solder material diffuses in the Ni film 13 from the surface 2b of the Ni film 13 to the semiconductor substrate 1 is formed and thus, the thickness of the alloy layer 4 is also shorter due to the fibrous-structure Ni film 13a. The Cu in the conductive plate 23 is eluted and diffuses in the solder plate 43, a portion of the conductive plate 23 and a portion of the solder plate 43 are alloyed, and the alloy layer 5 is also formed between the conductive plate 23 and the solder plate 43. As a result, the back electrode 2 and the conductive plate 23 are solder bonded via the solder layer 3. The solder layer 3 is a portion of the solder plate 43 that remains not alloyed (portion excluding the alloy layers 4 and 5). Conditions of the heat treatment are suitably set according to the size of the semiconductor substrate 1 and, for example, the temperature of the heat treatment may be about 320 degrees C to 330 degrees C and the treatment time may be about 10 minutes.

Thereafter, by a general method, the stacked substrate 21 to which the semiconductor substrate 1 is mounted is soldered to the metal substrate 25 so as to be housed in the case 26, and the predetermined wires 28, 30 are bonded to the front electrode of the semiconductor substrate 1. Subsequently, the case 26 is filled with the encapsulant 31, thereby protecting the semiconductor substrate 1, the stacked substrate 21, and the wires 28, 30, whereby the semiconductor module 20 depicted in FIG. 3 is completed.

As described, according to the embodiment, the Ni film of the back electrode has the fibrous-structure Ni film. In fibrous-structure Ni film, the solder material diffuses toward the semiconductor substrate during soldering of the back electrode, the solder material being detoured along the grain boundaries, in the lateral direction. Thus, the diffusion distance (length of the diffusion path) of the solder material in the Ni film is longer as compared to an instance in which the Ni film of the back electrode is configured by only a columnar-structure Ni film like that in the reference example (refer to FIG. 8). The linear distance that the solder material diffuses in the Ni film in the vertical direction to the semiconductor substrate may be reduced by the amount that the diffusion distance of the solder material is increased in the Ni film and thus, the thickness of the Ni film may be reduced. Production capacity of the product (semiconductor device) is improved while manufacturing cost and product unit cost may be reduced commensurate with the amount that the thickness of the Ni film is reduced.

Further, according to the embodiment, the deposition temperature and the gas pressure during the sputtering for the Ni film are suitably adjusted using the Thornton model to form the fibrous-structure Ni film. Thus, in a method of manufacturing an existing semiconductor device in which the Ni film of the back electrode is configured by only a columnar-structure Ni film, it suffices to form only the fibrous-structure Ni film in place of a portion of or the entire columnar-structure Ni film and thus, the disclosure may be easily applied to a method of manufacturing an existing semiconductor device.

In the disclosure above, without limitation to the embodiments described, various modifications within a range not departing from the spirit of the disclosure are possible. For example, the present disclosure is not limited to the back electrode of a semiconductor substrate and is applicable to a surface electrode that is formed on a main surface of a semiconductor substrate and soldered to a component.

The semiconductor device and the method of manufacturing a semiconductor device according to the present disclosure achieve an effect in that the thickness of the electrode layer may be reduced.

As described, the semiconductor device and the method of manufacturing a semiconductor device according to the present disclosure are useful for power semiconductor devices used in power converting equipment, power source devices such as those of various types of industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate with a main surface; and
a surface electrode provided at the main surface of the semiconductor substrate, the surface electrode having a nickel (Ni) film that includes a fibrous-structure Ni film, the fibrous-structure Ni film containing Ni crystal grains grown to form a fibrous shape.

2. The semiconductor device according to claim 1, wherein
the Ni film further includes a columnar-structure Ni film in contact with the fibrous-structure Ni film, the columnar-structure Ni film containing Ni crystal grains grown to form a columnar shape.

3. The semiconductor device according to claim 1, wherein
a percentage of a thickness of the fibrous-structure Ni film relative to a thickness of the Ni film is 50% or more but not more than 100%.

4. The semiconductor device according to claim 2, wherein
the Ni crystal grains of the fibrous-structure Ni film have crystal particle sizes that are larger than those of the Ni crystal grains of the columnar-structure Ni film.

5. The semiconductor device according to claim 1, wherein
the Ni crystal grains of the fibrous-structure Ni film have crystal particle sizes that are each 0.02 μm or more but not more than 0.2 μm.

6. The semiconductor device according claim 2, wherein
the Ni crystal grains of the columnar-structure Ni film have crystal particle sizes that are each 0.01 μm or more but not more than 0.05 μm.

7. A method of manufacturing a semiconductor device having
a semiconductor substrate with a main surface, and
a surface electrode provided at the main surface of the semiconductor substrate,
the method comprising:
as a deposition process, forming a nickel (Ni) film as the surface electrode, the Ni film being formed at the main surface of the semiconductor substrate, wherein
the deposition process includes performing a first sputtering at a temperature of 25 degrees C or higher but not more than 50 degrees C.

8. The method of manufacturing the semiconductor device according to claim 7, wherein
the deposition process includes performing the first sputtering under an argon (Ar) atmosphere at a gas pressure of 0.2 Pa or more but not more than 1.2 Pa.

9. The method of manufacturing the semiconductor device according to claim 7, wherein
the Ni film includes a first portion and a second portion that are mutually exclusive,
the first sputtering forms the first portion of the Ni film, and
the deposition process further includes subsequently performing a second sputtering under a temperature of 100 degrees C or higher but not more than 180 degrees C, to thereby form the second portion of the Ni film.
